(19) United States
(12) Patent Application Publication
(10) Pub. No.: US 2015/0099065 A1
(43) Pub. Date: Apr. 9, 2015

(54) GAS INJECTION COMPONENTS FOR DEPOSITION SYSTEMS, DEPOSITION SYSTEMS INCLUDING SUCH COMPONENTS, AND RELATED METHODS

(71) Applicant: Soitec, Crolles Cedex (FR)

(72) Inventors: Claudio Canizares, Chandler, AZ (US); Ronald Thomas Bertram, Jr., Mesa, AZ (US)

(21) Appl. No.: 14/401,386

(22) PCT Filed: May 24, 2013
(86) PCT No.: PCT/IB2013/001053

§ 371 Date: Nov. 14, 2014

Related U.S. Application Data
(60) Provisional application No. 61/656,725, filed on Jun. 7, 2012.

(51) Int. Cl. C23C 16/455

(52) U.S. Cl. CPC C23C 16/455
USPC 427/255.28; 118/715; 427/248.1

(57) ABSTRACT

Visor injectors include a gas injector port, internal sidewalls, and at least two ridges for directing gas flow through the visor injectors. Each of the ridges extends from a location proximate a hole in the gas injector port toward a gas outlet of the visor injector and is positioned between the internal sidewalls. Deposition systems include a base with divergently extending internal sidewalls, a gas injection port, a lid, and at least two divergently extending ridges for directing gas flow through a central region of a space at least partially defined by the internal sidewalls of the base and a bottom surface of the lid. Methods of forming a material on a substrate include flowing a precursor through such a visor injector and directing a portion of the precursor to flow through a central region of the visor injector with at least two ridges.

### CROSS-REFERENCE TO RELATED APPLICATIONS

This application is a national phase entry under 35 U.S.C. §371 of International Patent Application PCT/IB2013/001053, filed May 24, 2013, designating the United States of America and published in English as International Patent Publication WO2013/182878 A2 on Dec. 12, 2013, which claims the benefit under Article 8 of the Patent Cooperation Treaty to the U.S. Provisional Application Ser. No. 61/656,725, filed Jun. 7, 2012, the disclosure of each of which is hereby incorporated herein in its entirety by this reference.

### TECHNICAL FIELD

The present disclosure relates to gas injection components, such as visor injectors including injection ports, bases, and lids, for injecting gases into a chemical deposition chamber of a deposition system, as well as to systems including such components and methods of forming material on a substrate using such components and systems.

### BACKGROUND

Semiconductor structures are structures that are used or formed in the fabrication of semiconductor devices. Semiconductor devices include, for example, electronic signal processors, electronic memory devices, photoactive devices (e.g., light emitting diodes (LEDs), photovoltaic (PV) devices, etc.), and microelectromechanical (MEM) devices. Such structures and materials often include one or more semiconductor materials (e.g., silicon, germanium, silicon carbide, a III-V semiconductor material, etc.), and may include at least a portion of an integrated circuit.

Semiconductor materials formed of a combination of elements from Group III and Group V on the periodic table of elements are referred to as III-V semiconductor materials. Example III-V semiconductor materials include Group III-nitride materials, such as gallium nitride (GaN), aluminum nitride (AIN), aluminum gallium nitride (AlGaN), indium nitride (InN), and indium gallium nitride (InGaN). Hydride vapor phase epitaxty (HVPE) is a chemical vapor deposition (CVD) technique used to form (e.g., grow) Group III-nitride materials on a substrate.

In an example HVPE process for forming GaN, a substrate comprising silicon carbide (SiC) or aluminum oxide (Al₂O₃, often referred to as “sapphire”) is placed in a chemical deposition chamber and heated to an elevated temperature. Chemical precursors of gallium chloride (e.g., GaCl, GaCl₃) and ammonia (NH₃) are mixed within the chamber and react to form GaN, which epitaxially grows on the substrate to form a layer of GaN. One or more of the precursors may be formed within the chamber (i.e., in situ), such as when gallium chloride is formed by flowing hydrochloric acid (HCl) vapor across molten gallium, or one or more of the precursors may be formed prior to injection into the chamber (i.e., ex situ).

In prior known configurations, the precursor gallium chloride may be injected into the chamber through a generally planar gas injector having diverging internal sidewalls (often referred to as a “visor” or “visor injector”). The precursor NH₃ may be injected into the chamber through a multi-port injector. Upon injection into the chamber, the precursors are initially separated by a lid of the visor injector that extends to a location proximate an edge of the substrate. When the precursors reach the end of the lid, the precursors mix and react to form a layer of GaN material on the substrate.

### BRIEF SUMMARY

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In some embodiments, the present disclosure includes a visor injector including a gas injection port including a body, a hole therethrough, and a back wall proximate the hole. The visor injector also includes internal sidewalls extending from the back wall toward a gas outlet of the visor injector, and at least two ridges for directing gas flow through the visor injector. The at least two ridges each extend from a location proximate the hole toward the gas outlet. The at least two ridges are positioned between the internal sidewalls.

In some embodiments, the present disclosure includes a deposition system. The deposition system includes a base having divergently extending internal sidewalls, a gas injection port proximate ends of the internal sidewalls that are closest together, and a lid disposed over the base and the gas injection port. The deposition system also includes at least two divergently extending ridges for directing gas through a central region of a space at least partially defined by the internal sidewalls of the base and a bottom surface of the lid.

In some embodiments, the present disclosure includes methods of forming a material on a substrate. In accordance with such methods, a first precursor gas is flowed through a visor injector including a gas injection port, a base, and a lid. A portion of the first precursor gas is directed to flow through a central region of the visor injector with at least two ridges of the gas injection port formed between internal sidewalls of the gas injection port. The method also includes flowing the first precursor gas out of the visor injector and toward a substrate positioned proximate the visor injector.

### BRIEF DESCRIPTION OF THE DRAWINGS

While the specification concludes with claims particularly pointing out and distinctly claiming what are regarded as embodiments of the invention, the advantages of embodiments of the disclosure may be more readily ascertained from the description of certain examples of embodiments of the disclosure when read in conjunction with the accompanying drawings, in which:

FIG. 1 is a simplified partial perspective view of an embodiment of a chemical deposition chamber illustrating gas flow through the chemical deposition chamber through a visor injector and across a substrate, as calculated based on a computer model and simulation;

FIG. 2 illustrates a chart developed from a computer model and simulation showing mass fraction of a precursor across the substrate of FIG. 1 during a deposition process;

FIG. 3 is a graph developed from a computer model and simulation showing average precursor mass fractions across the substrate of FIG. 1 during a deposition process;

FIGS. 4A through 4C illustrate various views of a gas injection port according to an embodiment of the present disclosure;

FIG. 4A illustrates a top plan view of a gas injection port according to an embodiment of the present disclosure;

FIG. 4B illustrates a cross-sectional view of the gas injection port taken through section line 4B-4B of FIG. 4A;

FIG. 4C illustrates a perspective view of the gas injection port of FIGS. 4A and 4B;

FIG. 5 is an exploded perspective view of a visor injector according to an embodiment of the present disclosure including the gas injection port of FIG. 4A, a lid, and a base;

FIG. 6 illustrates a top view of the visor injector of FIG. 5 with the lid removed for clarity;

FIG. 7 illustrates gas flow through the visor injector of FIG. 5;

FIG. 8 illustrates a chart developed from a computer model and simulation showing mass fraction of a precursor across a substrate after the precursor is flowed through the visor injector of FIG. 5 during a deposition process;

FIG. 9 is a graph developed from a computer model and simulation showing average precursor mass fractions across the substrate of FIG. 8 during a deposition process;

FIGS. 10A through 10E illustrate various views of a lid according to another embodiment of the present disclosure;

FIG. 10A is a top plan view of a lid according to an embodiment of the present disclosure;

FIG. 10B is a bottom plan view of the lid of FIG. 10A;

FIG. 10C is a plan view of a portion of the bottom of the lid of FIGS. 10A and 10B;

FIG. 10D is a partial cross-sectional view of the lid of FIGS. 10A-10C taken along section line 10D-10D of FIG. 10C;

FIG. 10E is a perspective view of the lid of FIGS. 10A-10D;

FIG. 11A illustrates a visor injector according to an embodiment of the present disclosure including a base, the gas injection port of FIG. 4A, and the lid of FIG. 10A;

FIG. 11B illustrates the visor injector of FIG. 11A with portions of the lid removed for clarity;

FIG. 12 illustrates a model of gas flow through the visor injector of FIG. 11A;

FIG. 13 illustrates a chart developed from a computer model and simulation showing mass fraction of a precursor across a substrate after the precursor is flowed through the visor injector of FIG. 11A; and

FIG. 14 is a graph developed from a computer model and simulation showing average precursor mass fractions across the substrate of FIG. 13.

### DETAILED DESCRIPTION

The illustrations presented herein are not meant to be actual views of any particular material, structure, or device, but are merely idealized representations that are used to describe embodiments of the disclosure.

As used herein, the term “substantially,” in reference to a given parameter, property, or condition, means to a degree that one of ordinary skill in the art would understand that the given parameter, property, or condition is met within a degree of variance, such as within acceptable manufacturing tolerances.

As used herein, any relational term, such as “first,” “second,” “front,” “back,” “on,” “lower,” “top,” “bottom,” “opposite,” etc., is used for clarity and convenience in understanding the disclosure and accompanying drawings and does not connote or depend on any specific preference, orientation, or order, except where the context clearly indicates otherwise.

As used herein, the term “gas” means and includes a fluid that has neither independent shape nor volume. Gases include vapors. Thus, when the terms “gas” is used herein, it may be interpreted as meaning “gas or vapor.”

As used herein, the phrase “gallium chloride” means and includes one or more of gallium monochloride (GaCl) and gallium trichloride (GaCl₃). For example, gallium chloride may be substantially comprised of GaCl, substantially comprised of GaCL₃, or substantially comprised of both GaCl and GaCl₃.

The present disclosure includes structures and methods that may be used to flow gas toward a substrate, such as to deposit or otherwise form a material (e.g., a semiconductor material, a III-V semiconductor material, etc.) on a surface of the substrate. In particular embodiments, the present disclosure relates to visor injectors and components thereof (e.g., gas injection ports, bases, and lids), deposition systems using such visor injectors, methods of depositing or otherwise forming a semiconductor material on a substrate using such visor injectors, and methods of flowing gases through such visor injectors. One or more of the gas injection ports, bases, and lids of the visor injectors may include one or more ridges for directing gas flow through the visor injectors. Examples of such structures and methods are disclosed in further detail below.

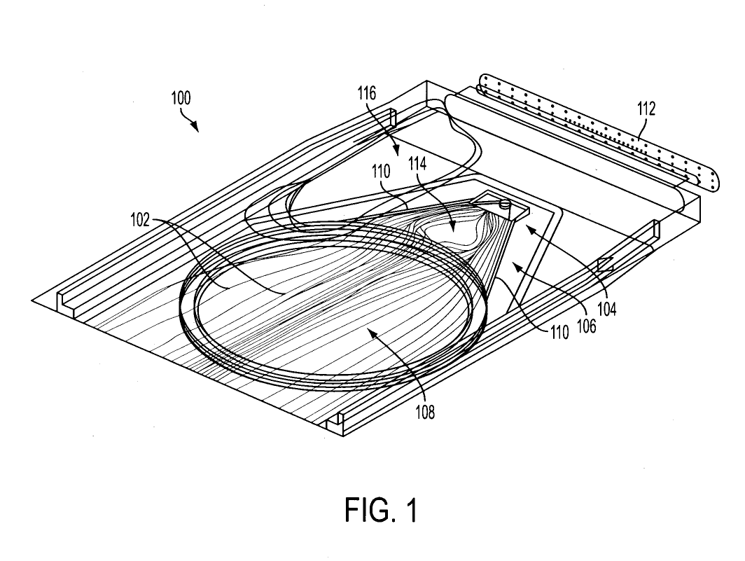

FIG. 1 illustrates a chamber 100 (e.g., an HVPE deposition chamber) of a deposition system and includes a computational fluid dynamics (CFD) model generally representing gas flowing through the chamber 100. Gas flow lines 102 are shown that represent a gallium chloride (e.g., GaCl, GaCl₃) flowing from a gas injection port 104, through a base 106, across a substrate 108, and in other portions of the chamber 100. A lid positioned over the gas injection port 104 and base 106 has been removed from FIG. 1 for clarity, although the model was generated based on an assumption that such a lid is present in the chamber 100. In addition, the model of FIG. 1 was generated assuming that ammonium (NH₃) is flowing from a multi-port injector 112 through the chamber 100, although such flow is not represented in FIG. 1 for clarity.

Although the present disclosure describes flowing a gallium chloride and NH₃ in the chamber 100 to form GaN on the substrate 108, the present disclosure is also applicable to flowing other gases, such as to form materials other than GaN. Indeed, one of ordinary skill in the art will recognize that the structures and methods of the present disclosure, as well as components and elements thereof, may be used in many applications that involve flowing one or more gases into and through a deposition chamber.

As shown in FIG. 1, the chamber 100 is a generally rectangular chamber in which a gallium chloride and NH₃ react to form a GaN material on the substrate 108 positioned generally centrally within the chamber 100. Gaseous gallium chloride may be injected into the chamber 100 through the gas injection port 104. The gallium chloride may flow out of the gas injection port 104 and through a base 106 with diverging internal sidewalls 110 that disperse the gallium chloride flow across the substrate 108. In addition, gaseous NH₃ may be injected into the chamber 100 through a multi-port injector 112. The gallium chloride and the NH₃ may be referred to herein generally as precursors. In addition, one or more purge gases, such as N₂, H₂, SiH₄, HCl, etc., may be injected into the chamber 100 along with the precursors, although such purge gases are not directly involved in the reaction to form the GaN material. One or both of the precursors may be heated prior to injection into the chamber 100. One method of heating the gallium chloride precursor prior to injection into the chamber 100 is disclosed in International Publication No. WO 2010/101715 A1, filed Feb. 17, 2010 and titled “GAS INJECTORS FOR CVD SYSTEMS WITH THE SAME,” the disclosure of which is incorporated herein in its entirety by this reference. The precursors may be preheated to more than about 500° C. In some embodiments, the precursors may be preheated to more than about 650° C., such as between about 700° C. and about 800° C. Prior to being heated, the gallium chloride precursor may be substantially comprised of gallium trichloride (GaCL₃). Upon heating and/or injection into the chemical deposition chamber, at least a portion of the GaCl₃ may thermally decompose into gallium monochloride (GaCl) and other byproducts, for example. Thus, in the chemical deposition chamber, the gallium chloride precursor may be substantially comprised of GaCl, although some GaCl₃ may also be present. In addition, the substrate 108 may also be heated prior to injection of the precursors, such as to more than about 500° C. In some embodiments, the substrate 108 may be preheated to a temperature between about 900° C. and about 1000° C.

The substrate 108 may comprise any material on which GaN or another desired material (e.g., another III-V semiconductor material) may be formed (e.g., grown, epitaxially grown, deposited, etc.). For example, the substrate 108 may comprise one or more of silicon carbide (SiC) and aluminum oxide (Al₂O₃, often referred to as “sapphire”). The substrate 108 may be a single, so-called “wafer” of material on which the GaN is to be formed, or it may be a susceptor (e.g., a SiC-coated graphite susceptor) for holding multiple smaller substrates of material on which the GaN is to be formed.

The configuration of the gas injection port 104 and the base 106 may cause a substantial portion of the gallium chloride to flow along the internal sidewalls 110 of the base 106, leaving a region 114 referred to herein as a “dead zone” in the center of the base 106 where relatively little gallium chloride flows. Such a dead zone 114 may contribute to a region of recirculation 116 of gallium chloride, for example. The recirculation 116 of the gallium chloride may contribute to non-uniform gallium chloride flow distribution over the substrate 108. For example, the presence of the dead zone 114 in the base 106 may contribute to a relatively heavier concentration of gallium chloride flow across a central portion of the substrate 108, as shown in FIG. 1, which may lead to increased GaN material thickness in the central portion of the substrate 108. In addition, recirculation of the gallium chloride may reduce the controllability and predictability of the gas flows through the chamber 100, as well as of the process of forming the GaN material on the substrate 108.

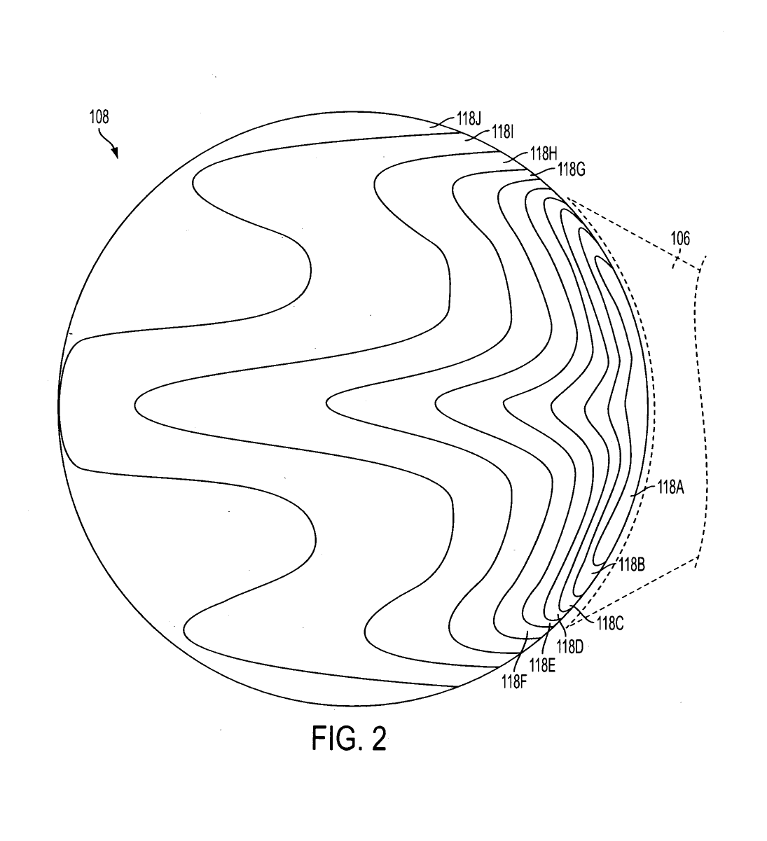

FIG. 2 illustrates a chart (developed from a CFD model) representing gallium chloride mass fraction across the surface of the substrate 108 during operation of the chamber 100 of FIG. 1. The contours shown in FIG. 2 represent boundaries between areas 118A through 118J having different ranges of gallium chloride mass fractions, decreasing from right to left when viewed from the perspective of FIG. 2. Accordingly, the rightmost area 118A may represent the relatively highest gallium chloride mass fraction range, the adjacent area 118B may represent the relatively next highest gallium chloride mass fraction range, and so forth. The leftmost area 118J may represent the relatively lowest gallium chloride mass fraction range.

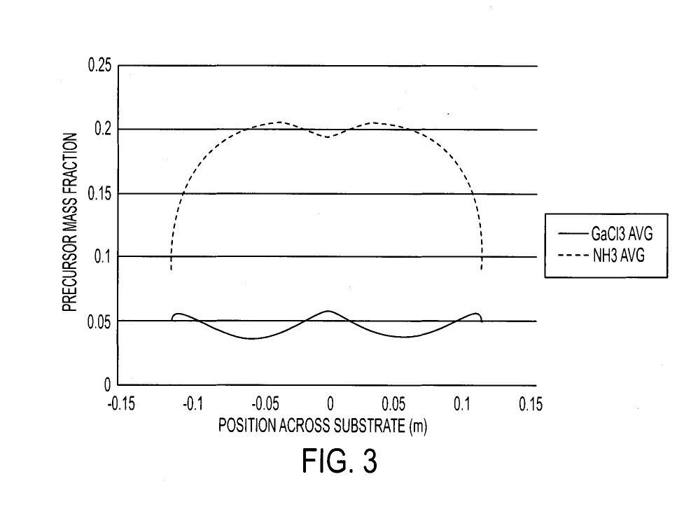

FIG. 3 illustrates a graph showing average precursor mass fractions of NH₃ and gallium chloride as a function of position from a center of the substrate 108. The substrate 108 may be rotated during the HVPE process to improve the uniformity of the GaN material formation on the substrate 108. Thus, the graph of FIG. 3 was produced by averaging precursor mass fraction data at varying locations across the substrate 108 to estimate the precursor mass fractions across a rotating substrate 108.

Referring to FIGS. 2 and 3 in conjunction with FIG. 1, the dead zone 114 and recirculation 116 of the gallium chloride may result in a relatively non-uniform mass fraction of gallium chloride across the substrate 108. The non-uniformity of the gallium chloride mass fraction may correlate to non-uniform GaN formation on the substrate 108. As shown in FIG. 3, a center (i.e., at graphical position zero meters (0 m)) and outer edges (i.e., at graphical positions −0.1 m and 0.1 m) of the substrate 108 may exhibit relatively high mass fractions of gallium chloride, while an area between the center and outer edges of the substrate 108 may exhibit relatively lower mass fractions of gallium chloride. Thus, the model indicates that GaN being formed on the substrate 108 under the conditions on which the model is based may be relatively thick at the center and outer edges of the substrate 108 and relatively thin in an area between the center and outer edges.

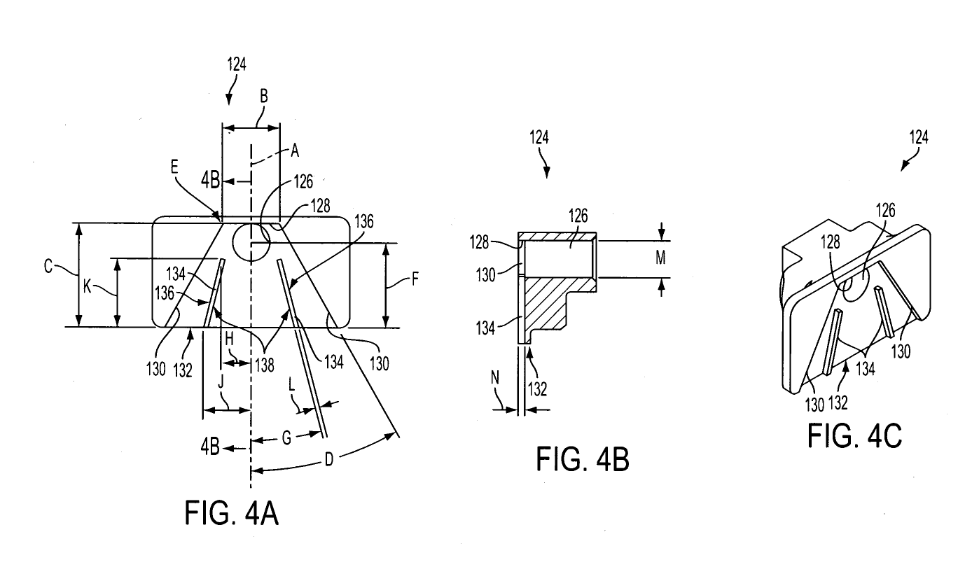

FIGS. 4A through 4C illustrate various views of a gas injection port 124 according to the present disclosure. A hole 126 may extend through a body of the gas injection port 124 through which gaseous gallium chloride flows, such as out of the page when viewed in the perspective of FIG. 4A and from right to left when viewed in the perspective of FIG. 4B. In some embodiments, the hole 126 may extend through a body of the gas injection port 124 such that a back wall 128 of the gas injection port 124 is at least substantially tangential to the hole 126. In addition, the hole 126 may be at least substantially centrally located between internal sidewalls 130 divergently extending from the back wall 128 toward a front face 132 of the gas injection port 124. The gas injection port 124 may also include ridges 134 positioned between the internal sidewalls 130 that may divergently extend from a location proximate the hole 126 toward the front face 132. Each of the ridges 134 may have an outer first side 136 and an inner second side 138.

At least portions of the gas injection port 124 that affect gas flow (e.g., the hole 126, the back wall 128, the internal sidewalls 130, the ridges 134) may be located substantially symmetrically about an axis of symmetry A extending centrally through the gas injection port 124 from the back wall 128 to the front face 132. As shown in FIG. 4A, each of the ridges 134 may be positioned at least substantially centrally between an adjacent internal sidewall 130 and the axis of symmetry A.

Although the sizing, dimensions, shapes, and configurations of the various elements of the gas injection port 124 are subject to modification, such as for flowing different gases, for flowing gases of different temperatures, for flowing gases at different velocities, for forming a material on a different-sized substrate, etc., example dimensions will be described for one embodiment of the gas injection port 124 suitable for flowing gaseous gallium chloride therethrough at a sufficient temperature and velocity to react with NH₃ to form a GaN material on a substrate.

According to one embodiment, as shown in FIG. 4A, the back wall 128 may extend in a direction generally parallel to the front face 132 for a length B of between about 0.125 inch (0.32 cm) and about 0.75 inch (1.91 cm), such as about 0.472 inch (1.20 cm), for example. A distance C from the back wall 128 to the front face 132 parallel to the axis of symmetry A and perpendicular to the back wall 128 may be between about 0.5 inch (1.27 cm) and about 2.0 inches (5.08 cm), such as about 0.855 inch (2.17 cm), for example. Each of the internal sidewalls 130 may extend from the back wall 128 to the front face 132 at an angle D of between about fifteen degrees)(15° and about forty-five degrees)(45°, such as about thirty degrees)(30° from the axis of symmetry A, for example. An intersection between the back wall 128 and each of the internal sidewalls 130 may be curved with a radius E of between about 0 inch (0 cm) (i.e., a sharp corner) and about 0.25 inch (0.64 cm), such as about 0.04 inch (0.10 cm), for example. A distance F between a center of the hole 126 and the front face 132 parallel to the axis of symmetry A may be between about 0.25 inch (0.64 cm) and about 1.9 inches (4.83 cm), such as about 0.7 inch (1.78 cm), for example. Each of the ridges 134 may extend from a location proximate the hole 126 toward the front face 132 at an angle G from the axis of symmetry A of between about zero degrees)(0° (i.e., parallel to the axis of symmetry A) and about forty-five degrees)(45°, such as about fourteen and one-half degrees)(14.5°, for example. A distance H between the axis of symmetry A and an end of the outer first side 136 of each ridge 134 proximate the hole 126 may be between about 0.1 inch (0.25 cm) and about 0.75 inch (1.91 cm), such as about 0.25 inch (0.64 cm), for example. A distance J between the axis of symmetry A and an end of the outer first side 136 of each ridge 134 at the front surface 132 may be between about 0.1 inch (0.25 cm) and about 1.75 inches (4.45 cm), such as about 0.36 inch (0.91 cm), for example. A length K of each ridge 134 taken parallel to the axis of symmetry A may be between about 0.4 inch (1.02 cm) and about 1.9 inches (4.83 cm), such as about 0.569 inch (1.45 cm), for example. Each of the ridges 134 may have a width L between the outer first side 136 and the inner second side 138 thereof of between about 0.01 inch (0.03 cm) and about 0.125 inch (0.32 cm), such as about 0.039 inch (0.10 cm), for example.

As shown in FIG. 4B, the hole 126 may have a diameter M of between about 0.2 inch (0.51 cm) and about 0.5 inch (1.27 cm), such as about 0.31 inch (0.79 cm), for example. Each of the back wall 128, the internal sidewalls 130, and the ridges 134 may protrude from a major surface of the gas injection port 124 a height N of between about 0.02 inch (0.05 cm) and about 0.125 inch (0.32 cm), such as about 0.05 inch (0.13 cm), for example. Other portions of the gas injection port 124 may be any convenient shape and size for assembling with a base and/or a lid. For example, outer surfaces of the gas injection port 124 may have a shape and size that is complementary to a cavity of a base, such that the gas injection port 124 may be seated at least partially within the cavity.

Although the internal sidewalls 130 and the ridges 134 of the gas injection port 124 are shown as being substantially linear, the present disclosure is not so limited. For example, one or more of the internal sidewalls 130 and the ridges 134 may alternatively extend along a curved path or along a stepped path.

The gas injection port 124 may be formed of any material that can sufficiently maintain its shape under the conditions (e.g., chemicals, temperatures, flow rates, pressures, etc.) to which the gas injection port 124 will be subjected during operation. Additionally, the material of the gas injection port 124 may be selected to inhibit reaction with gas (e.g., a precursor) flowing therethrough. By way of example and not limitation, the gas injection port 124 may be formed of one or more of a metal, a ceramic, and a polymer. In some embodiments, the gas injection port 124 maybe at least substantially comprised of quartz, such as clear fused quartz that is fire polished, for example. In some embodiments, the gas injection port 124 may comprise a SiC material. The gas injection port 124 may be cleaned prior to installation within a chemical deposition chamber to reduce contaminants in the chamber, such as with a 10% hydrofluoric (HF) acid solution, followed by a rinse with distilled and/or deionized water, for example.

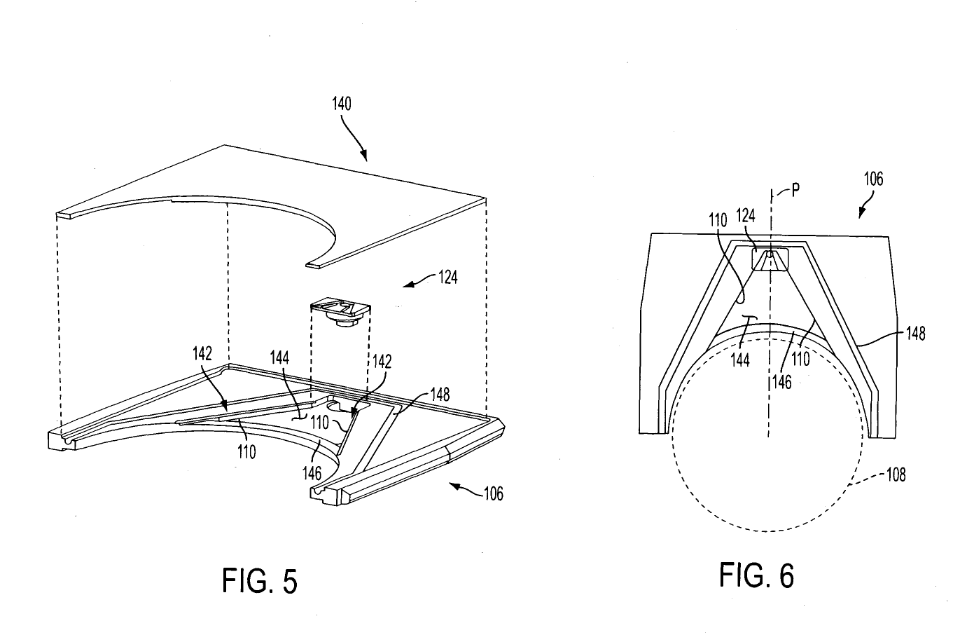

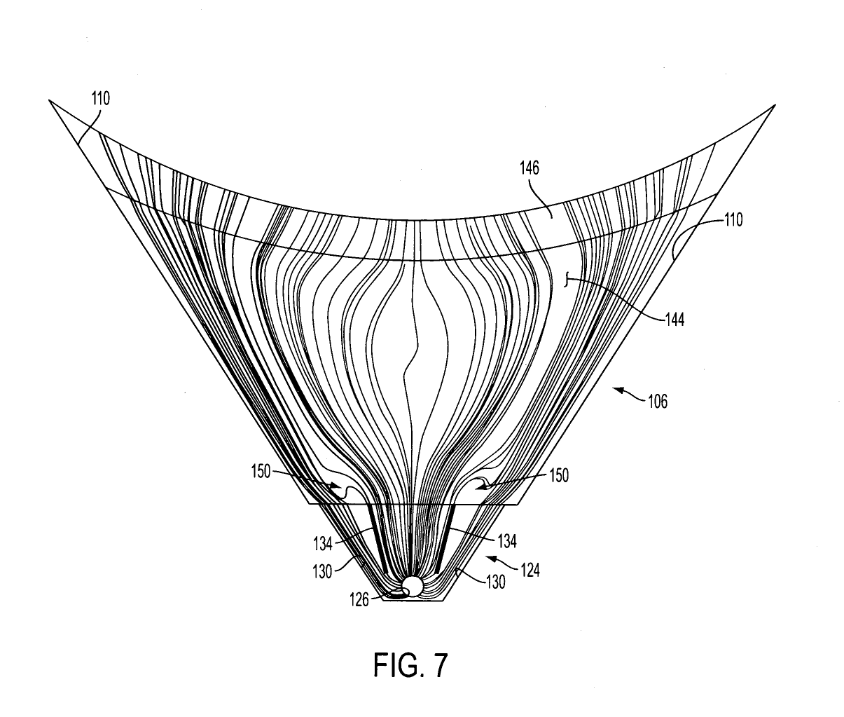

Referring to FIG. 5, the gas injection port 124 may be assembled with a base 106 and a lid 140, as indicated by phantom lines, to form a visor injector for installation within a chemical deposition chamber. The lid 140 may be sized and configured to fit complementarily over the base 106 and the gas injection port 124. FIG. 6 shows a top view of the assembled gas injection port 124 and the base 106, with the lid 140 removed for clarity. Each of the base 106 and the lid 140 may comprise one or more of a metal, a ceramic, and a polymer. In some embodiments, one or both of the base 106 and the lid 140 may comprise a quartz material. In some embodiments, one or both of the base 106 and the lid 140 may comprise a SiC material.

Although the visor injector is shown in FIG. 5 as comprising the separately formed base 106, lid 140, and gas injection port 124 that are assembled together to form the visor injector, the present disclosure is not so limited. For example, any two or all three of the base 106, the lid 140, and the gas injection port 124 may be formed as a unitary body. In some embodiments, the base 106 and the gas injection port 124 may be portions of a unitary body. In other embodiments, the lid 140 and the gas injection port 124 may be portions of a unitary body.

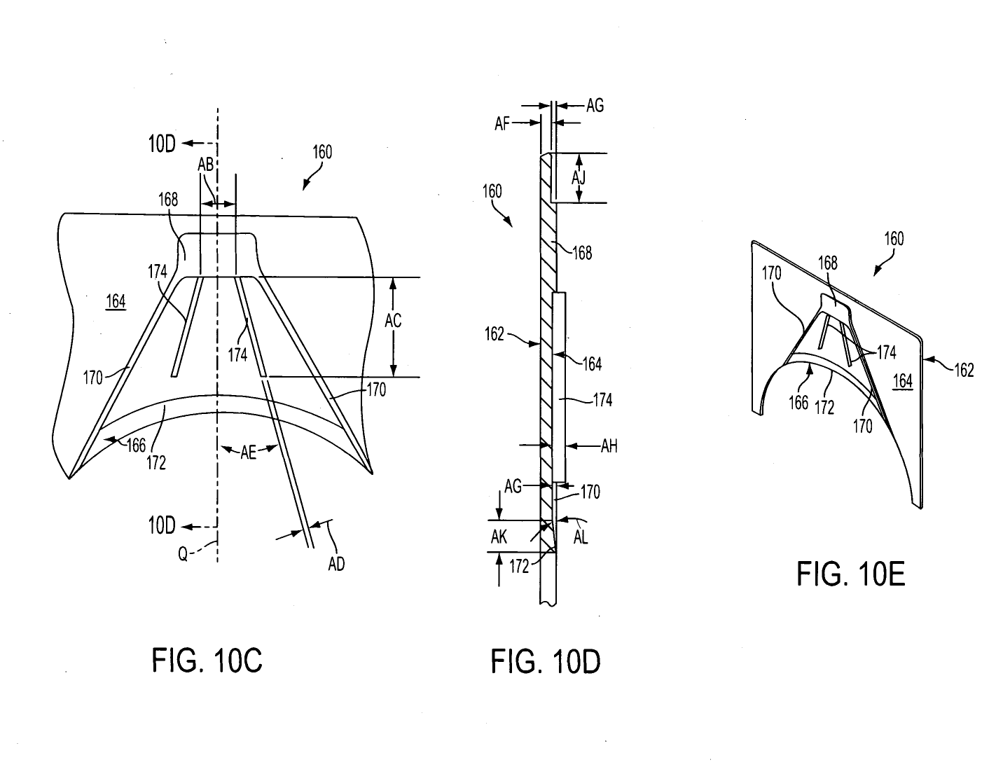

Referring to FIGS. 5 and 6, the base 106 may include internal sidewalls 110 that divergently extend from a location proximate the gas injection port 124 to a location proximate a substrate 108 upon which GaN, for example, is to be formed during an HVPE process. The internal sidewalls 110 of the base 106 may extend at an angle from an axis of symmetry P that may be at least substantially the same as the angle D (FIG. 4A) at which the internal sidewalls 130 (FIG. 4A) of the gas injection port 124 extend, such as about 30° from the axis of symmetry P. The axis of symmetry P may extend midway between the internal sidewalls 110. A recess 142 may be formed along each of the internal sidewalls 110 of the base 106 for disposing a feature of the lid 140 in the recess 142, as will be explained in more detail below with reference to a lid 160 of FIGS. 10A through 10E. In some embodiments, the internal sidewalls 110 of the base 106 may extend in an at least substantially similar direction as the internal sidewalls 130 of the gas injection port 124 extend, and the internal sidewalls 110 of the base 106 may be continuous with the internal sidewalls 130 of the gas injection port 124. In other embodiments, the internal sidewalls 110 of the base 106 may extend in a different direction than the internal sidewalls 130 of the gas injection port 124. In some embodiments, the internal sidewalls 110 of the base 106 may extend along a curved (e.g., concave or convex) path or a stepped path.

An at least substantially planar surface 144 may extend between the internal sidewalls 110 of the base 106. The base 106 may also include a lip 146 along a curved terminal edge of the base 106 that extends from one of the internal sidewalls 110 to the other. The lip 146 may at least partially define a gas outlet of the base 106. Optionally, the base 106 may include one or more channels 148 through which another gas (e.g., a purge gas, such as H₂, N₂, SiH₄, HCl, etc.) may be introduced into the chamber.

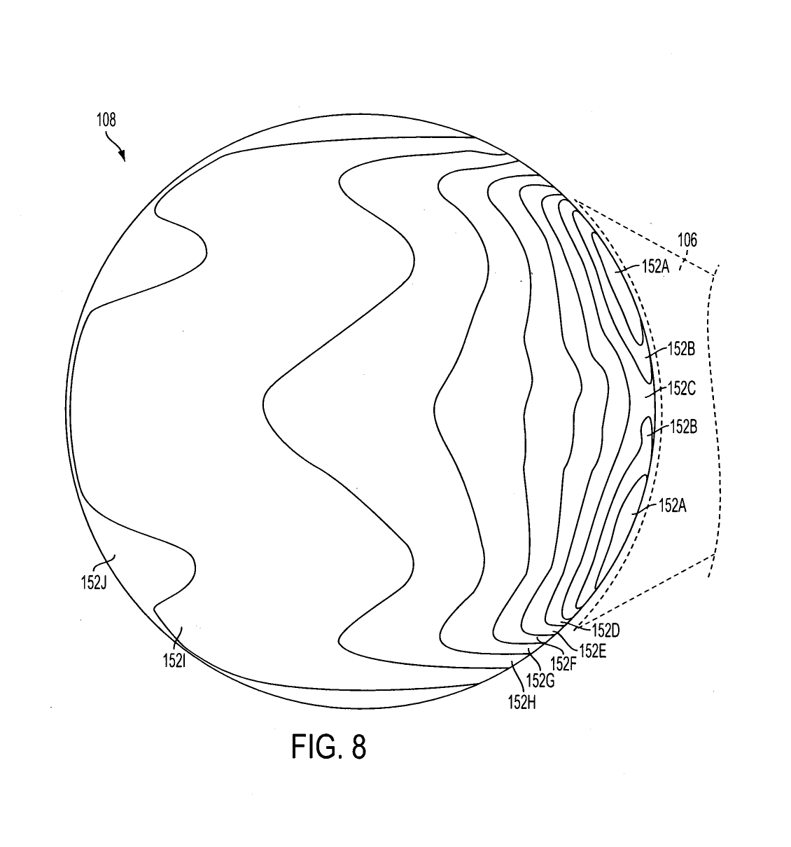

FIG. 7 illustrates a CFD model of gas flow through the visor injector of FIG. 5. For clarity, only portions of the gas injection port 124 and of the base 106 along which gas flows are shown, and the lid 140 is not shown in FIG. 7. Gas (e.g., gallium chloride) may be injected through the hole 126 of the gas injection port 124 and into a volume between the surface 144, the internal sidewalls 130 and 110, and the lid 140 (FIG. 5). As a volume of the space through which the gas expands due to the divergence of the internal sidewalls 130 and 110, a velocity of the gas may be reduced, and the gas may be dispersed from a relatively narrow flow at the gas injection port 124 to a relatively wider flow over the lip 146.

As shown in FIG. 7, gas flowing out of the hole 126 may be directed toward the lip 146 of the base 106 by the ridges 134 in a more uniform manner compared to the flow shown in FIG. 1, wherein the gas injection port 104 does not include any ridges 134. The ridges 134 may, therefore, reduce and/or eliminate the dead zone 114 shown in FIG. 1 by directing gas toward a central region of the base 106. Although some gas recirculation 150 may occur in the flow through the assembled gas injection port 124, base 106, and lid 140 (FIG. 5), such gas recirculation 150 may be reduced compared to the gas recirculation 116 shown in FIG. 1. In addition, gas exiting the base 106 over the lip 146 in FIG. 7 may be distributed relatively more uniformly than gas exiting the base 106 in FIG. 1.

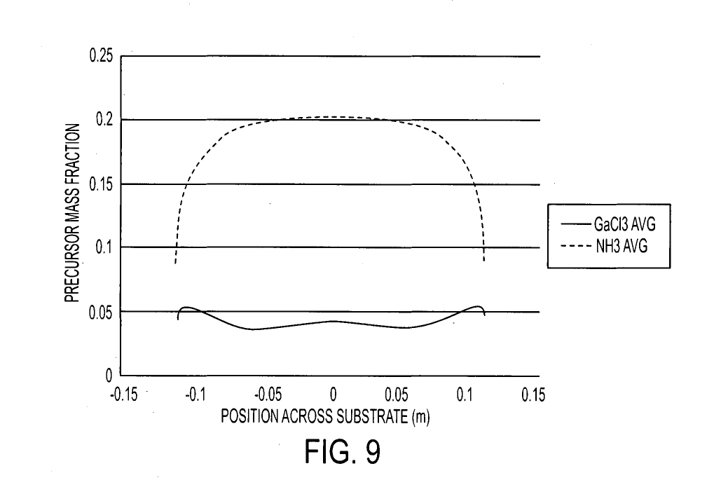

FIG. 8 illustrates a CFD model representing gallium chloride mass fraction across the surface of the substrate 108 resulting from flowing gallium chloride through the visor injector comprising the gas injection port 124, the base 106, and the lid 140. The contours shown in FIG. 8 represent boundaries between areas 152A through 152J having different ranges of gallium chloride mass fractions, decreasing from right to left when viewed in the perspective of FIG. 8. Accordingly, the area 152A may represent the relatively highest gallium chloride mass fraction range, the adjacent area 152B may represent the relatively next highest gallium chloride mass fraction range, and so forth. The leftmost area 152J may represent the relatively lowest gallium chloride mass fraction range. As can be seen by comparing the chart of FIG. 8 with the chart of FIG. 2, the contour lines in the chart of FIG. 8 exhibit less deviation in the lateral left and right directions moving across the substrate in the vertical up and down directions (from the perspectives of the figures).

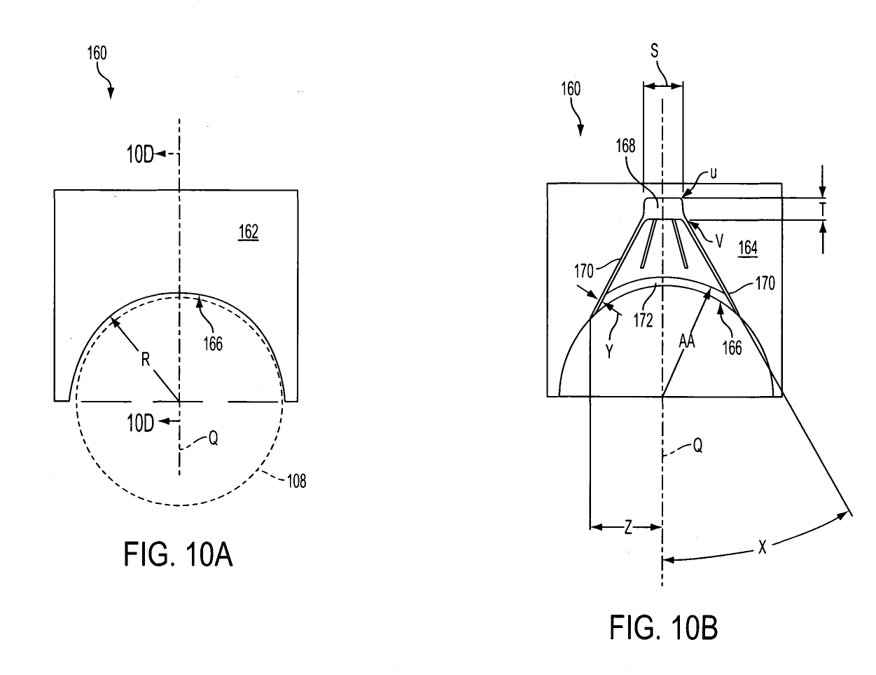

FIG. 9 illustrates a graph showing average precursor mass fractions of NH₃ and gallium chloride as a function of position from a center of the substrate 108 resulting from flowing gallium chloride through the visor injector comprising the gas injection port 124, the base 106, and the lid 140. The substrate 108 may be rotated during the HVPE process to improve the uniformity of the GaN material formation on the substrate 108. Thus, the graph of FIG. 9 was produced by averaging precursor mass fraction data at varying locations across the substrate 108 to estimate the precursor mass fractions across a rotating substrate 108.

Referring to FIGS. 8 and 9 in conjunction with FIG. 7, the gas injection port 124 including the ridges 134 may direct gallium chloride flowing therethrough to be more uniformly distributed across the substrate 108 when compared to the embodiment shown and modeled in FIGS. 1 through 3. The improved uniformity of the gallium chloride mass fraction may correlate to improved uniformity in GaN material formation on the substrate 108. Comparing the graph of FIG. 9 to the graph of FIG. 3, the average gallium chloride mass fraction across the substrate 108 may be relatively more uniform when the gallium chloride is directed through the gas injection port 124 (FIG. 7) than when the gallium chloride is directed through the gas injection port 104 (FIG. 1). Accordingly, a thickness of the GaN material formed on the substrate 108 from a precursor gallium chloride flowed through the gas injection port 124 and the base 106 may have improved uniformity across the substrate 108. For example, GaN material with an average thickness of about 5 μm formed using a prior known visor injector may have a standard deviation in layer thickness of about 20% of the average thickness. In contrast, a GaN material with an average thickness of about 5 μm formed according to the present disclosure may have a standard deviation in layer thickness of about 10% or less of the average thickness.

In some embodiments, the present disclosure also includes methods of forming a material (e.g., a semiconductor material, such as a III-V semiconductor material) on a substrate. Referring again to FIGS. 4A through 7, the gas injection port 124, the base 106, and the lid 140 may be assembled as described above and positioned within a chemical deposition chamber similar to the chamber 100 shown in FIG. 1. The substrate 108 (shown in FIG. 6 in dashed lines) may be positioned proximate the assembled gas injection port 124, base 106, and lid 140. The substrate 108 may be rotated within the chamber. The substrate 108 may be heated to an elevated temperature, such as above about 500° C. In some embodiments, the substrate 108 may be preheated to a temperature between about 900° C. and about 1000° C.

A first precursor gas (e.g., gaseous gallium chloride) may be flowed through the hole 126 in the gas injection port 124 and into a space between the gas injection port 124 and the lid 140 positioned over the gas injection port 124. The velocity of the first precursor gas may be reduced by the provision of the diverging internal sidewalls 130 of the gas injection port 124. The first precursor gas may be directed through the gas injection port 124 by one or more of the ridges 134 divergently extending from a location proximate the hole 126 to proximate the front face 132 of the gas injection port 124. One of the ridges 134 may be positioned generally centrally between a first internal sidewall of the internal sidewalls 130 and the axis of symmetry A, and another of the ridges 134 may be positioned generally centrally between a second internal sidewall of the internal sidewalls 130 and the axis of symmetry A. A portion of the first precursor gas may be directed to flow between the first internal sidewall 130 and an adjacent ridge 134, another portion of the first precursor gas may be directed to flow between the ridges 134, and yet another portion of the first precursor gas may be directed to flow between the second internal sidewall 130 and an adjacent ridge 134. Directing the first gas precursor through the gas injection port 124 may, as a result, direct the first gas precursor to flow through a central region of the assembled gas injection port 124, lid 140, and base 106. Example details of additional characteristics (e.g., size, shape, material, angles, etc.) of the gas injection port 124 and components thereof through which the first precursor gas may be flowed are described above.

After the first precursor gas is flowed through the gas injection port 124, the first precursor gas may be flowed between the base 106 and the lid 140 from the gas injection port 124 toward the substrate 108. The velocity of the first precursor gas may be additionally reduced by the provision of the diverging internal sidewalls 110 of the base 106. The first precursor gas may be directed over the lip 146 provided along a curved terminal edge of the base 106 to exit the visor injector comprising the gas injection port 124, the base 106, and the lid 140. The first precursor gas may then be flowed over the substrate 108.

A second precursor gas (e.g., gaseous NH₃) may be injected into the chamber, such as through the multi-port injector 112 described above with reference to FIG. 1, and flowed along a major surface of the lid 140 opposite the first precursor gas and in generally the same direction as the flow of the first precursor gas. Optionally, one or more purge gases (e.g., H₂, N₂, SiH₄, HCl, etc.) may also be flowed in the chamber, such as through the channels 148 of the base 106 (FIGS. 5 and 6), as described above. One or more of the first precursor gas, the second precursor gas, and the purge gas(es) may be heated prior to, upon, and/or after entering the chamber. For example, one or more of the first precursor gas, the second precursor gas, and the purge gas(es) may be preheated to a temperature above about 500° C. In some embodiments, the one or more of the first precursor gas, the second precursor gas, and the purge gas(es) may be preheated to more than about 650° C., such as between about 700° C. and about 800° C.

After the first precursor gas exits the visor injector comprising the gas injection port 124, the base 106, and the lid 140, and after the second precursor gas reaches an end of the lid 140 proximate the substrate 108, the first and second precursor gases may be mixed to react and to form (e.g., grow, epitaxially grow, deposit, etc.) a material on the substrate 108. The material formed on the substrate 108 may be a semiconductor material comprising compounds (e.g., III-nitride compounds, e.g., GaN compounds) of at least one atom from the first precursor gas (e.g., Ga) and at least one atom from the second precursor gas (e.g., N). Portions of the first and second precursor gases that do not form a material on the substrate 108 (e.g., Cl and H, such as in the form of HCl) may be flowed out of the chamber along with the purge gas(es). Using the gas injection port 124 having the ridges 134 to direct flow of the first precursor gas in the manner described may enable improved uniformity of thickness of the material formed on the substrate 108.

FIGS. 10A through 10E illustrate various views of another embodiment of a lid 160 of the present disclosure. The lid 160 may be sized and configured to fit complementarily over the base 106 and the gas injection port 124, in a similar manner to the lid 140 shown in FIG. 5. As shown in FIGS. 10A through 10C, the lid 160 may be at least substantially symmetrical about an axis of symmetry Q. Referring to FIGS. 10A through 10E, the lid 160 may include a top major surface 162 and a bottom major surface 164 opposite the top major surface 162. The top major surface 162 may be at least substantially planar. A gas outlet side 166 of the lid 160 may be substantially semicircular and concave for partially circumscribing a substrate 108 to be positioned proximate the gas outlet side 166 during operation. Thus, precursor gases (e.g., gallium chloride and NH₃) on either side of the lid 160 may be at least substantially isolated from each other by the lid 160 until the precursor gases reach a location proximate an edge of the substrate 108, as shown by dashed lines in FIG. 10A.

As shown in FIGS. 10B through 10E, the bottom major surface 164 of the lid 160 may include several features protruding therefrom. A protrusion 168 may be sized and shaped so as to be disposed over the gas injection port 124 when assembled therewith (FIGS. 5 and 6), such as to fit at least partially inside a cavity in the base 106 in which the gas injection port 124 is positioned. Diverging ribs 170 may extend from the protrusion 168 to the gas outlet side 166 and may be sized and shaped so as to extend along the internal sidewalls 110 of the base 106 when assembled therewith (FIGS. 5 and 6). As noted above, the base 106 may include recesses 142 (FIG. 5) formed along the internal sidewalls 110 thereof. At least a portion of each of the diverging ribs 170 of the lid 160 may be positioned within one of the recesses 142 of the base 106 when assembled therewith. As shown in FIGS. 10B through 10E, the diverging ribs 170 may protrude from the bottom major surface 164 of the lid 160 to at least substantially the same extent as the protrusion 168.

A sloped gas outlet surface 172 may extend at an angle from the bottom major surface 164 to the gas outlet side 166 of the lid 160 to substantially the same height that the diverging ribs 170 protrude from the bottom major surface 164. Ridges 174 may divergently extend from the protrusion 168 toward the gas outlet side 166. The ridges 174 may protrude from the bottom major surface 164 of the lid 160 to a greater extent than the protrusion 168 (as shown in FIGS. 10D and 10E). Each of the ridges 174 may be positioned at least substantially centrally between an adjacent diverging rib 170 and the axis of symmetry Q. An end portion of each of the ridges 174 proximate the protrusion 168 may be positioned to be proximate ends of the ridges 134 of the gas injection port 124 at the front face 132 of the gas injection port 124 (FIGS. 4A and 4C) when assembled therewith. For example, the ridges 174 of the lid 160 may be configured to be at least substantially collinear and continuous with the ridges 134 of the gas injection port 124 when assembled therewith.

Although the sizing, dimensions, shapes, and configurations of the various elements of the lid 160 are subject to modification, such as for flowing different gases, for flowing gases of different temperatures, for flowing gases at different velocities, for forming a material on a different-sized substrate 108, etc., example dimensions will be described for one embodiment of the lid 160 suitable for flowing gaseous gallium chloride at a sufficient temperature and velocity to react with NH₃ and to form GaN on a substrate.

According to one embodiment, as shown in FIG. 10A, the gas outlet side 166 of the lid 160 may have a radius R of between about 4 inches (10.16 cm) and about 6.5 inches (16.51 cm), such as about 4.50 inches (11.43 cm), for example.

As shown in FIG. 10B, the protrusion 168 may have first width S of between about 1 inch (2.54 cm) and about 3 inches (7.62 cm), such as about 1.650 inches (4.19 cm), for example. A second width T perpendicular to the first width S may be between about 0.6 inch (1.52 cm) and about 2.5 inches (6.35 cm), such as about 0.925 inch (2.35 cm), for example. Corners of the protrusion 168 on a side thereof opposite the gas outlet side 166 of the lid 160 may have a radius U of between about zero inch (0 cm) (i.e., a sharp corner) and about 0.25 inch (0.64 cm), such as about 0.13 inch (0.33 cm), for example. The diverging ribs 170 may extend at least substantially continuously from corners of the protrusion 168. At an intersection between each of the diverging ribs 170 and the protrusion 168, an internal radius V between an edge of the protrusion 168 and the diverging rib 170 may be between about zero inch (0 cm) (i.e., a sharp corner) and about 0.5 inch (1.27 cm), such as about 0.25 inch (0.64 cm), for example. Each of the diverging ribs 170 may extend from the protrusion 168 to the gas outlet side 166 at an angle X of between about fifteen degrees)(15° and about forty-five degrees)(45°, such as about 29.3°, for example. Each of the diverging ribs 170 may have a lateral width Y of between about 0.05 inch (0.13 cm) and about 0.25 inch (0.64 cm), such as about 0.095 inch (0.24 cm), for example. A distance Z between an outer surface of an end of each of the diverging ribs 170 proximate the gas outlet side 166 of the lid 160 and the axis of symmetry Q may be between about 2 inches (5.08 cm) and about 4 inches (10.16 cm), such as about 3.10 inches (7.87 cm), for example. An edge of the sloped gas outlet surface 172 intersecting the bottom major surface 164 may have a radius AA of between about 4.2 inches (10.67 cm) and about 7 inches (17.78 cm), such as about 4.850 inches (12.32 cm), for example.

As shown in FIG. 10C, an internal distance AB between ends of the ridges 174 proximate the protrusion 168 may be between about 0.2 inch (0.51 cm) and about 3.5 inches (8.89 cm), such as about 0.72 inch (1.83 cm), for example. Each of the ridges 174 may have a length AC taken parallel to the axis of symmetry Q of between about 1 inch (2.54 cm) and about 3 inches (7.67 cm), such as about 1.97 inches (5.00 cm), for example. Each of the ridges 174 may have a lateral width AD of between about 0.01 inch (0.03 cm) and about 0.125 inch (0.32 cm), such as about 0.039 inch (0.10 cm), for example. An angle AE between the axis of symmetry Q and each ridge 174 may be between about zero degrees)(0° (i.e., parallel to the axis of symmetry Q) and about forty-five degrees)(45°, such as about fourteen and one-half degrees)(14.5°, for example.

As shown in FIG. 10D, the lid 160 may have a thickness AF between the top major surface 162 and the bottom major surface 164 of between about 0.05 inch (0.13 cm) and about 0.375 inch (0.95 cm), such as about 0.100 inch (0.25 cm), for example. The protrusion 168 and the diverging ribs 170 may protrude from the bottom major surface 164 a distance AG of between about 0.02 inch (0.05 cm) and about 0.125 inch (0.32 cm), such as about 0.045 inch (0.11 cm), for example. The ridges 174 may protrude from the bottom major surface 164 a distance AH of between about 0.02 inch (0.05 cm) and about 0.25 inch (0.64 cm), such as about 0.145 inch (0.37 cm), for example. An end surface of the lid 160 opposite the gas outlet side 166 (FIG. 10E) may be a distance AJ of about 0.25 inch (0.64 cm) and about 1 inch (2.54 cm), such as about 0.520 inch (1.32 cm), for example, from an edge of the protrusion 168 opposite the gas outlet side 166. The sloped gas outlet surface 172 may have a width AK, taken parallel to the bottom major surface 164 and extending from an intersection with the bottom major surface 164 to the gas outlet side 166 of the lid 160, of between about 0.2 inch (0.51 cm) and about 0.5 inch (1.27 cm), such as about 0.350 inch (0.89 cm), for example. The sloped gas outlet surface 172 may extend from the bottom major surface 164 to the gas outlet side 166 at an angle AL of between about two degrees (2°) and about fifteen degrees (15°), such as about seven degrees (7°), for example.

The lid 160 may be formed of any material that can sufficiently maintain its shape under the conditions (e.g., chemicals, temperatures, flow rates, pressures, etc.) to which the lid 160 will be subjected during operation. Additionally, the material of the lid 160 may be selected to inhibit reaction with gas (e.g., precursors) flowing against and/or along the lid 160. By way of example and not limitation, the lid 160 may be formed of one or more of a metal, a ceramic, and a polymer. In some embodiments, the lid 160 may comprise a quartz material, such as clear fused quartz that is fire polished, for example. The lid 160 may be cleaned prior to installation within a chemical deposition chamber to reduce contaminants in the chamber, such as with a 10% HF acid solution, followed by a rinse with distilled and/or de-ionized water, for example.

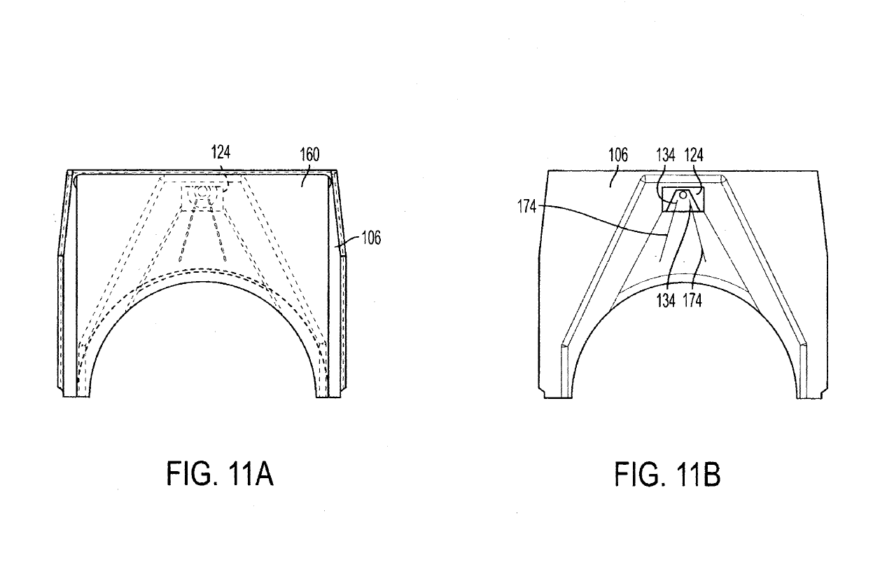

As shown in FIGS. 11A and 11B, the base 106, the gas injection port 124, and the lid 160 may be assembled. In FIG. 11A, the gas injection port 124 and portions of the base 106, as well as features of the lid 160, are shown in dashed lines since these components and features are positioned under the lid 160 in the perspective of FIG. 11A. In FIG. 11B, portions of the lid 160 other than the ridges 174 are removed to more clearly show areas through which a gas (e.g., gaseous gallium chloride) may flow. As shown in FIGS. 11A and 11B, the ridges 134 of the gas injection port 124 may be at least substantially aligned and continuous with the ridges 174 of the lid 160 when the base 106, the gas injection port 124, and the lid 160 are assembled.

Although the visor injector is shown in FIGS. 11A and 11B as comprising the separately formed base 106, lid 160, and gas injection port 124 that are assembled together to form the visor injector, the present disclosure is not so limited. For example, any two or all three of the base 106, the lid 160, and the gas injection port 124 may be formed as a unitary body, essentially as described above with reference to the base 106, the lid 140, and the gas injection port 124 of FIG. 5.

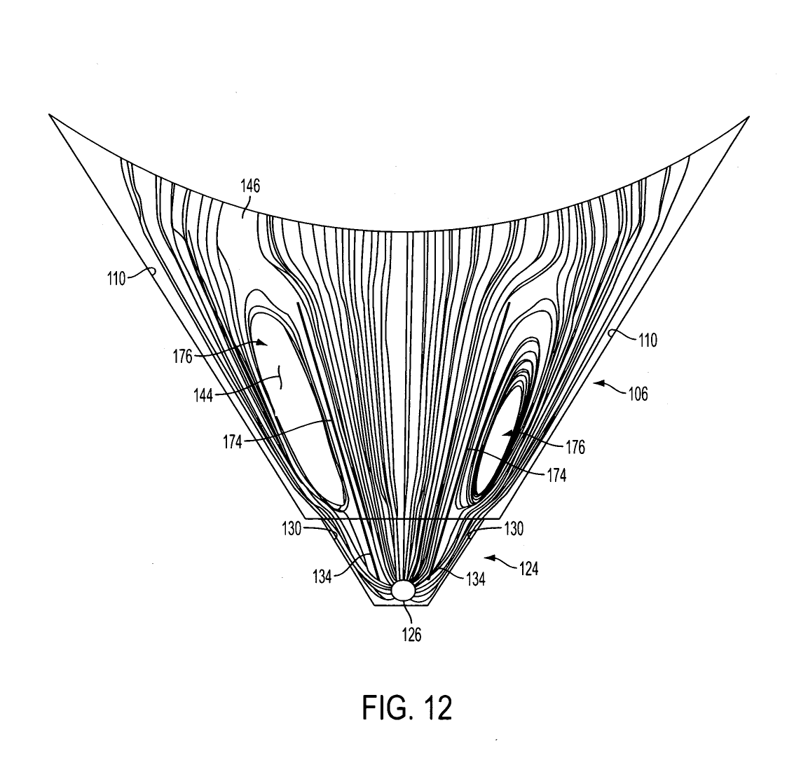

FIG. 12 illustrates a CFD model of gas flow through the assembled gas injection port 124, base 106, and lid 160 (FIGS. 11A and 11B). For clarity, only portions of the gas injection port 124, of the base 106, and of the lid 160 along which gas flows are shown in FIG. 12. Referring to FIG. 12, gas (e.g., gaseous gallium chloride) may be injected through the hole 126 of the gas injection port 124 and into a volume between the surface 144, the internal sidewalls 130 and 110, and the lid 160 (FIGS. 11A and 11B). As the volume expands due to the divergence of the internal sidewalls 130 and 110, a velocity of the gas may be reduced, and the gas may be dispersed from a relatively narrow flow at the gas injection port 124 to a relatively wider flow over the lip 146.

As shown in FIG. 12, gas flowing out of the hole 126 may be directed toward the lip 146 of the base 106 by the ridges 134 of the gas injection port 124 in a more uniform manner compared to the flow shown in FIG. 1, wherein the gas injection port 104 does not include any ridges. Additionally, gas flowing from the gas injection port 124 toward the lip 146 (and ultimately to a substrate positioned proximate the lip 146) may be further guided and distributed by the ridges 174 of the lid 160 (FIGS. 11A and 11B). The ridges 134 and 174 may, therefore, reduce and/or eliminate the dead zone 114 shown in FIG. 1 by directing gas toward a central region of the base 106. The CFD model of FIG. 12 illustrates that some gas recirculation 176 may occur in the flow through the base 106 between the ridges 174 and the internal sidewalls 110 of the base 106. Although the gas recirculation 176 may be increased from the gas recirculation 150 shown in FIG. 7, such gas recirculation 176 may be reduced compared to the gas recirculation 116 shown in FIG. 1. In addition, even though some recirculation 176 may occur along the ridges 174, gas exiting the base 106 over the lip 146 in FIG. 12 may be distributed relatively more uniformly than gas exiting the base 106 in FIG. 1.

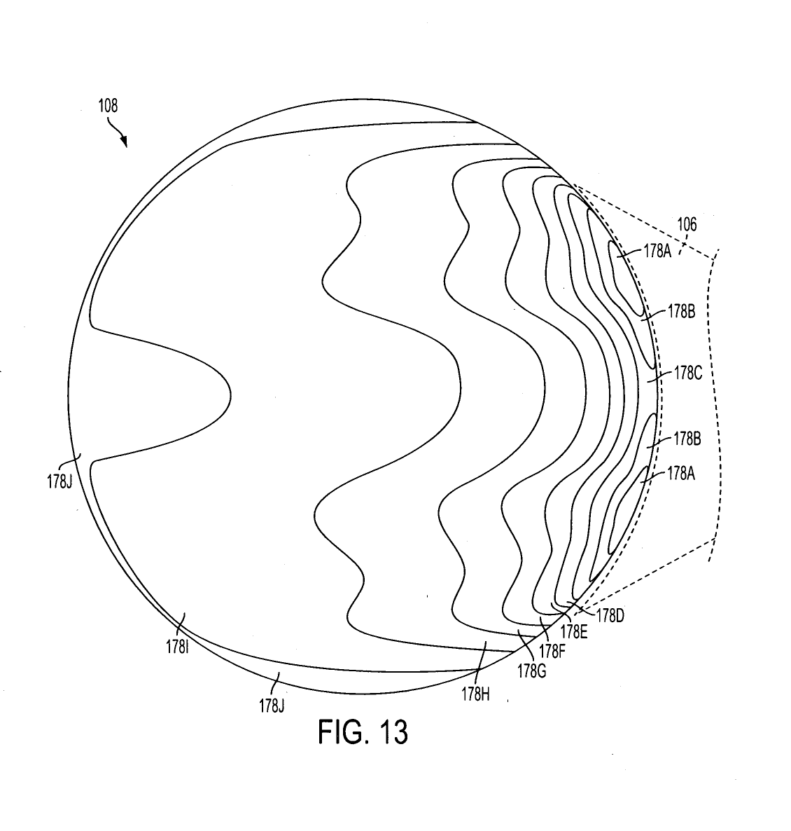

FIG. 13 illustrates a CFD model representing gallium chloride mass fraction across the surface of the substrate 108 resulting from flowing gallium chloride through the visor injector comprising the gas injection port 124, the base 106, and the lid 160. The contours shown in FIG. 13 represent boundaries between areas 178A through 178J having different ranges of gallium chloride mass fractions, decreasing from right to left when viewed in the perspective of FIG. 13. Accordingly, the area 178A may represent the relatively highest gallium chloride mass fraction range, the adjacent area 178B may represent the relatively next highest gallium chloride mass fraction range, and so forth. The leftmost area 178J may represent the relatively lowest gallium chloride mass fraction range. As can be seen by comparing the chart of FIG. 13 with the chart of FIG. 2, the contour lines in the chart of FIG. 13 exhibit less deviation in the lateral left and right directions moving across the substrate in the vertical up and down directions (from the perspectives of the figures).

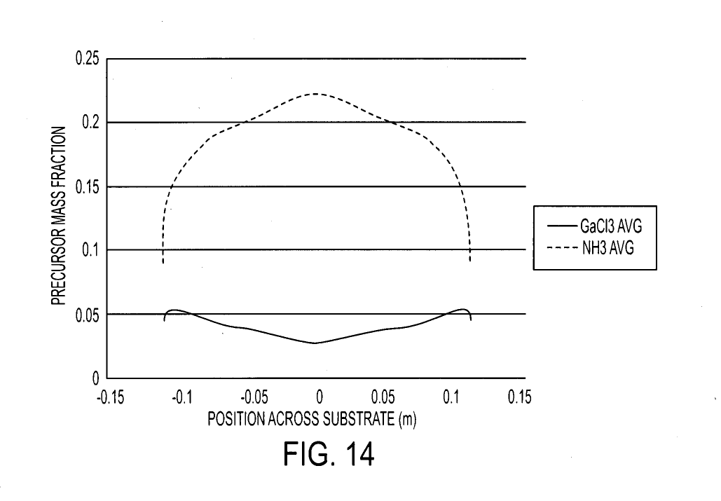

FIG. 14 illustrates a graph showing average precursor mass fractions of NH₃ and GaCl₃ as a function of position from a center of the substrate 108 resulting from flowing gallium chloride through the visor injector comprising the gas injection port 124, the base 106, and the lid 160. The substrate 108 may be rotated during the HVPE process to improve the uniformity of the GaN material formation on the substrate 108. Thus, the graph of FIG. 14 was produced by averaging precursor mass fraction data at varying locations across the substrate 108 to estimate the precursor mass fractions across a rotating substrate 108.

Referring to FIGS. 13 and 14 in conjunction with FIG. 12, the gas injection port 124 including the ridges 134 and the lid 160 including the ridges 174 (FIGS. 11A and 11B) may direct gallium chloride flowing therethrough to be more uniformly distributed across the substrate 108 when compared to the embodiment shown and modeled in FIGS. 1 through 3. The improved uniformity of the gallium chloride mass fraction may correlate to improved uniformity in GaN material formation on the substrate 108. Comparing the graph of FIG. 14 to the graph of FIG. 3, the average gallium chloride mass fraction across the substrate 108 may be relatively more uniform when the gallium chloride is directed through the assembled gas injection port 124, lid 160, and base 106 than when the gallium chloride is directed through the gas injection port 104 (FIG. 1). Accordingly, a thickness of the GaN material formed on the substrate 108 from a precursor gallium chloride flowed through the assembled gas injection port 124, the lid 160, and base 106 may have improved uniformity across the substrate 108.

Although the lid 160 with the ridges 174 is shown in FIGS. 11A through 12 being used in conjunction with the gas injection port 124 with the ridges 134, the present disclosure is not so limited. For example, in some embodiments, the lid 160 having the ridges 174 may be assembled with the base 106 and the gas injection port 104, which lacks any ridges.

In addition, although the gas injection port 124 has been described above as including the ridges 134 extending therefrom with reference to FIGS. 4A through 4C and the lid 160 has been described above as including the ridges 174 protruding from a bottom surface 164 thereof with reference to FIGS. 10B through 1 OE, the present disclosure is not so limited. By way of example, the ridges 134 described as extending from the gas injection port 124 may alternatively extend from the protrusion 168 of the lid 160 shown in FIGS. 10B through 10E. By way of another example, the ridges 174 described as protruding from the lid 160 may alternatively protrude from the surface 144 of the base 106 (FIGS. 5 through 7).

In some embodiments, the present disclosure includes additional methods of forming a material (e.g., a semiconductor material, such as a III-V semiconductor material) on a substrate. Referring again to FIGS. 10A through 12, the gas injection port 124, the base 106, and the lid 160 may be assembled as described above and positioned within a chemical deposition chamber similar to the chamber 100 of FIG. 1. The substrate 108 (shown in FIG. 1 OA in dashed lines) may be positioned proximate the assembled gas injection port 124, base 106, and lid 160. The substrate 108 may be rotated within the chamber. The substrate 108 may be heated to an elevated temperature, such as above about 500° C. In some embodiments, the substrate 108 may be preheated to a temperature between about 900° C. and about 1000° C.

A first precursor gas (e.g., gaseous gallium chloride) may be flowed through the hole 126 in the gas injection port 124 and into a space between the gas injection port 124 and the lid 160 positioned over the gas injection port 124, essentially as described above with reference to FIGS. 4A through 7. Alternatively, the first precursor gas may be flowed through a gas injection port lacking any ridges, such as the gas injection port 104 shown in FIG. 1.

After the first precursor gas is flowed through the gas injection port 124, the first precursor gas may be flowed between the base 106 and the lid 160 from the gas injection port 124 toward the substrate 108. The velocity of the first precursor gas may be additionally reduced by the provision of the diverging internal sidewalls 110 of the base 106. The first precursor gas may be directed through the base 106 by one or more of the ridges 174 divergently extending along the lid 160 from a location proximate the gas injection port 124 toward the gas outlet side 166 of the lid 160. One of the ridges 174 may be positioned generally centrally between a first diverging rib of the diverging ribs 170 and the axis of symmetry Q of the lid 160. Another of the ridges 174 may be positioned generally centrally between a second diverging rib of the diverging ribs 170 and the axis of symmetry Q. A portion of the first precursor gas may be directed to flow between a first internal sidewall 110 of the base 106 and an adjacent ridge 174, another portion of the first precursor gas may be directed to flow between the ridges 174, and yet another portion of the first precursor gas may be directed to flow between a second internal sidewall 110 of the base 106 and an adjacent ridge 174. The first precursor gas may be directed to flow between the lip 146 provided along a curved terminal edge of the base 106 and the sloped gas outlet surface 172 of the lid 160 to exit the visor injector comprising the gas injection port 124, the base 106, and the lid 160. Example details of additional characteristics (e.g., size, shape, material, angles, etc.) of the lid 160 and components thereof along which the first precursor gas may be flowed are described above. The first precursor gas may then be flowed over the substrate 108.

Essentially as described above, a second precursor gas may be flowed along the top major surface 162 of the lid 160 (FIGS. 10A and 10D) opposite the flow of the first precursor gas and in generally the same direction as the flow of the first precursor gas, and the first and second precursor gases may be mixed to react and to form a material on the substrate 108. Using the lid 160 having the ridges 174 to direct flow of the first precursor gas in the manner described may enable improved uniformity of thickness of the material formed on the substrate 108.

Referring again to FIGS. 4A through 7, a visor injector of the present disclosure may include a generally planar space at least partially defined by the internal sidewalls 110, 130 divergently extending from the hole 126 of the gas injection port 124 toward the lip 146 along the curved terminal edge of the base 106, the at least substantially planar surface 144 of the base 106, and a surface of the lid 140. The ridges 134 may be disposed within the space to divergently extend from a location proximate the hole 126 of the gas injection port 124 toward the lip 146. As explained above, each of the ridges 134 may be positioned within the space in the visor injector at least substantially centrally between an adjacent internal sidewall 110, 130 and an axis of symmetry extending midway between opposing internal sidewalls 110, 130. The ridges 134 may be sized and positioned to guide and distribute gas flowing through the visor injector, such as to guide a portion of the gas toward a central region of the space in the visor injector. Referring again to FIGS. 10B through 12, the space in a visor injector of the present disclosure may alternatively and/or additionally be at least partially defined by a bottom major surface 164 of the lid 160. The ridges 174 of the lid 160 may be disposed within the space in addition to or instead of the ridges 134 of the gas injection port 124. The ridges 174 may divergently extend through the space and may be sized and positioned to guide and distribute gas flowing through the visor injector, such as to guide a portion of gas toward a central region of the space in the visor injector.

The example embodiments of the disclosure described above do not limit the scope of the invention, since these embodiments are merely examples of embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A visor injector, comprising:
a gas injection port including a body, a hole extending through the body, and a back wall proximate the hole;
internal sidewalls extending from the back wall toward a gas outlet of the visor injector; and
at least two ridges for directing gas flow through the visor injector, the at least two ridges each extending from a location proximate the hole toward the gas outlet, the at least two ridges positioned between the internal sidewalls.

2. The visor injector of claim 1, wherein the internal sidewalls divergently extend from the back wall toward the gas outlet.

3. The visor injector of claim 1, wherein the at least two ridges divergently extend from the location proximate the hole to a front face of the gas injection port.

4. The visor injector of claim 1, wherein the hole, the back wall, the internal sidewalls, and the at least two ridges are at least substantially symmetrical about an axis of symmetry.

5. The visor injector of claim 4, wherein each ridge of the at least two ridges extends from the location proximate the hole toward the gas outlet at an angle of between about zero degrees 0°) and about forty-five degrees (45°) from the axis of symmetry.

6. The visor injector of claim 4, wherein each ridge of the at least two ridges is positioned at least substantially centrally between an adjacent internal sidewall of the internal sidewalls and the axis of symmetry.

7. The visor injector of claim 1, wherein the back wall is at least substantially tangential to the hole.

8. The visor injector of claim 1, wherein the gas injection port is at least substantially comprised of quartz.

9. The visor injector of claim 1, further comprising:
a base; and
a lid.

10. The visor injector of claim 9, wherein at least two of the gas injector port, the base, and the lid are formed as a unitary body.

11. A method of forming a material on a substrate, the method comprising:
flowing a first precursor gas through a visor injector including a gas injection port, a base, and a lid;
directing a portion of the first precursor gas to flow through a central region of the visor injector with at least two ridges of the gas injection port formed between internal sidewalls of the gas injection port; and
flowing the first precursor gas out of the visor injector and toward a substrate positioned proximate the visor injector.

12. The method of claim 11, further comprising:
flowing a second precursor gas along a major surface of the lid opposite the first precursor gas; and
reacting the first precursor gas and the second precursor gas to form a material on the substrate.

13. The method of claim 12, wherein:
flowing a first precursor gas through a visor injector comprises directing gallium chloride through the visor injector;
flowing a second precursor gas along a major surface of the lid opposite the first precursor gas comprises flowing ammonium along the major surface of the lid; and
reacting the first precursor gas and the second precursor gas to form a material on the substrate comprises epitaxially growing a gallium nitride material on the substrate.

14. The method of claim 11, further comprising directing the portion of the first precursor gas to flow through the central region of the visor injector with at least two additional ridges formed on a surface of the lid and extending from a location proximate the gas injection port toward a gas outlet side of the lid.

15. The method of claim 11, further comprising heating the first precursor gas to a temperature above about five hundred degrees Celsius (500° C.) prior to flowing the first precursor gas through the visor injector.

16. A deposition system, comprising:
a base including divergently extending internal sidewalls;
a gas injection port proximate ends of the divergently extending internal sidewalls that are closest together;
a lid disposed over the base and the gas injection port; and
at least two divergently extending ridges for directing gas flow through a central region of a space at least partially defined by the divergently extending internal sidewalls of the base and a bottom surface of the lid.

17. The deposition system of claim 16, wherein each of the gas injection port and the lid includes at least two divergently extending ridges.

18. The deposition system of claim 17, wherein the at least two divergently extending ridges of the lid are at least substantially collinear with the at least two divergently extending ridges of the gas injection port.

19. The deposition system of claim 16, wherein:
at least one of the visor and the lid includes at least two divergently extending ridges; and
each ridge of the at least two divergently extending ridges is positioned at least substantially centrally between an internal sidewall of the divergently extending internal sidewalls and an axis of symmetry extending midway between the divergently extending internal sidewalls.

20. The deposition system of claim 16, further comprising a chemical deposition chamber, wherein the base, the gas injection port, and the lid are disposed inside the chemical deposition chamber.
